(19) United States
(12) Patent Application Publication
(10) Pub. No.: US 2001/0052100 A1
(43) Pub. Date: Dec. 13, 2001

(54) Data read/write controlling method, disk array apparatus, and recording medium for recording data read/write controlling program

(75) Inventor: Kenichi Miki, Tokyo (JP)

Correspondence Address: David A. Blumenthal, FOLEY & LARDNER, Washington Harbour, 3000 K Street N.W., Suite 500, Washington, DC, 20007-5109, US

(73) Assignee: NEC CORPORATION

(21) Appl. No.: 09/878,270

(22) Filed: Jun. 12, 2001

(30) Foreign Application Priority Data
Jun. 13, 2000 (JP) 2000-177036

(51) Int. Cl. G11C 29/00; G06F 12/00

(52) U.S. Cl. 714/768; 711/112

(57) ABSTRACT

The invention includes an array controlling unit 5 for writing predetermined data to and reading it out from a disk and also conducting operational processing on this data, which array controlling unit 5 has a data dividing section 7 for dividing the predetermined data into at least two data items and also generating parity data based on this predetermined data, a plurality of cache modules 9, 10, and 11 for temporarily storing these divided data items and the parity data respectively, and a data combining section 8 for repairing the divided data item stored in one of these cache modules, if it fails, using the other divided data items and the parity data and also combining the divided data item.

### BACKGROUND OF THE INVENTION

1. Field of the Invention

The invention relates to a disk array apparatus and, more particularly to, a disk array apparatus that gives redundancy in particular to data and stores this data to a disk.

2. Description of the Related Art

Conventionally, data has been transferred between an upper-level host system and a disk via a cache memory in order to improve the rate at which the data is written to and read out from a disk drive.

Also, the prior art disk array apparatus employs a method to further improve the reliability in data retention, such as disclosed in Japanese Patent Application Laid-Open No. Hei 11-312058, whereby the same data is previously copied in two caches so that if one of them is damaged, the other may transfer the data stored therein.

Specifically, this prior art disk array apparatus has such a configuration as shown in FIG. 3 to implement cache redundancy. The cache redundancy is implemented in this configuration by previously copying (mirroring) the same data via an internal data bus 112 in both cache modules 109 and 110.

The above-mentioned method of mirroring the same data, however, can assign only half the capacity of the mounted caches as the data storage capacity, thus suffering from a problem of incapability of transferring the mass of data.

Besides, by this method, if one of the two modules fails, the other cache module cannot give a caching function, thus giving rise to also a problem of deteriorating the I/O performance of the host system.

### SUMMARY OF THE INVENTION

It is an object of the invention to solve the above-mentioned problems of the prior art implementation particularly to repair the data in the case of a cache failure to thereby maintain the data transfer reliability and increase the ratio of assigning the capacity of the mounted caches to the storage of data in order to enable mass data transfer, thus providing a data read/write controlling method and a disk array apparatus that can prevent a deterioration in the I/O performance for the host system and a recording medium for recording the data read/write controlling program.

In order to achieve the above-mentioned object, present invention comprises: a data receiving step of receiving predetermined data to be rewritten to a disk from an upper-level host system; a data processing step of conducting predetermined processing on the received data; and a data write-in step of writing the processed data to the disk.

And the data processing step comprises: a data dividing step of dividing the data received at the data receiving step into a plurality of data items and also generating parity data; a data storing step of individually storing the divided data items and parity data items into cache modules respectively; a data repairing step of fetching the divided data items and the parity data from the cache modules and repairing one of the divided data items if damaged, using the parity data; and a data combining step of combining the divided data items.

For this reason, in the present invention, the data received from the upper-level host system are divided into a plurality of data items, and parity data of these data are generated. Those divided data items and the parity data are individually stored in the respective cache modules. Those divided data items and the parity data are fetched from the cache modules, and if one of the divided data items is damaged, the damaged divided data item is repaired based on the parity data. After that, those divided data items are combined and written to the disk. So if the transfer data are damaged, they can be repaired without mirroring, thus mass data transfer can be obtained while maintaining a high reliability in transfer of the data.

Moreover, the present invention comprises: a data read-out step of reading out predetermined data to be transmitted to the upper-level host system from a disk; a data processing step of conducting predetermined processing on the read out data; and a data transmitting step of transmitting the processed data to the upper-level host system.

And the data processing step comprises: a data dividing step of dividing the data read out at the data read-out step into a plurality of data items and also generating parity data; a data storing step of individually storing the divided data items and parity data items into cache modules respectively; a data repairing step of fetching the divided data items and the parity data from the cache modules and also repairing one of the divided data if damaged, using the parity data; and a data combining step of combining the divided data.

For this reason, in the present invention, if transfer data are damaged, they can be repaired without mirroring transfer data, so mass data transfer can be achieved while maintaining a high reliability in transfer of the data.

A disk array apparatus comprises an array controlling unit for receiving an instruction from the upper-level host system to thereby write predetermined data to or read the predetermined data out from a disk and also conduct operational processing on the predetermined data, wherein the array controlling unit comprises: a data dividing function for dividing the predetermined data into at least two data items and also generating parity data for the predetermined data; and a data combining function for repairing one of the divided data items if damaged, using the parity data and also combining the divided data items.

For this reason, in the present invention, the parity data are generated based on the predetermined data and also predetermined data including the parity data are divided into at least two data, and if one of the divided data items is damaged, it can be repaired by using the parity data. Therefore, mass data transfer can be achieved without mirroring transfer data while maintaining a high reliability in transfer of the data.

Moreover, the present invention comprises a disk array apparatus having an array controlling unit for receiving an instruction from the upper-level host system to thereby write predetermined data to or reading the predetermined data from a disk and also conduct operational processing on the predetermined data.

And the array controlling unit comprises: a data dividing section for dividing the predetermined data into at least two data items and also generating parity data based on the predetermined data; a plurality of cache modules for temporarily storing the divided data items and the parity data respectively; and a data combining section for repairing the divided data item stored in one of the cache modules, if the one fails, using the remaining ones of the divided data items and the parity data and also combining the divided data.

For this reason, in the present invention, the predetermined data are divided into at least two data items and parity data are generated based on the predetermined data by the data dividing section. And these divided data items and the parity data are stored in a plurality of cache modules respectively. After this, data items are combined by the data combining section based on the divided data items and the parity data.

If one of the cache modules fails and one of the divided data items stored therein is damaged, this damaged divided data item can be repaired by the data combining section based on remaining divided data items and the parity data to there by combine the data items in order to transfer the data using the remaining normal cache modules while maintaining a data transfer reliability and so prevent the I/O performance from being deteriorated.

Moreover, the present invention comprises the disk array apparatus, wherein the cache modules are set to have an equal capacity.

For this reason, the present invention has a function, the cache modules are set to have an equal capacity or each divided data item and the part data are set to have an equal capacity, then each cache module or each divided data item and the parity data have an equal capacity, so that each divided data and the parity data need not be generated based on each capacity to thereby simplify the generation method, thus improving the processing rate and also providing an excellent effect of reducing the costs because a single type of cache modules can be used.

Moreover, the present invention comprises the disk array apparatus, wherein each of the divided data items and the parity data are set to have an equal capacity.

For this reason, the present invention has a function, the cache modules are set to have an equal capacity or each divided data item and the part data are set to have an equal capacity, then each cache module or each divided data item and the parity data have an equal capacity, so that each divided data and the parity data need not be generated based on each capacity to thereby simplify the generation method, thus improving the processing rate.

Moreover, the present invention comprises the disk array apparatus, wherein a total number of the divided data items and the parity data items are set equal to a number of the cache modules.

For this reason, the present invention has a function, the divided data items or the parity data are stored in each cache module respectively, thus giving an excellent effect of utilizing the capacity of the cache memory.

Moreover, the present invention comprises the disk array apparatus, wherein a number of the divided data items are set one smaller than a number of the cache modules.

For this reason, the present invention has a function, one of the cache modules can be assigned for storing the parity data to thereby assign the other cache modules for storing of the divided data items, thus giving an excellent effect of utilizing the capacity of the cache memory in data transfer further effectively for improved mass data transfer.

Moreover, the present invention comprises a data dividing process for receiving predetermined data to be written to a disk from the upper-level host system to then divide the predetermined data into a plurality of data items and also generate parity data; a data storing process for individually storing the divided data items and the parity data into cache modules respectively; a data repairing process for fetching the divided data items and the parity data from the cache modules to thereby repair one of the divided data item, if the one is damaged, using the parity data; and a data combining process of combining the divided data items to then write thus combined data to the disk.

For this reason, the present invention has a function, if transfer data are damaged, they can be repaired without mirroring transfer data, therefore mass data transfer can be achieved while maintaining a high reliability in transfer of the data.

### BRIEF DESCRIPTION OF THE DRAWINGS

The above and other objects, advantages, and features of the invention will be more apparent from the following description taken in conjunction with the accompanying drawings, in which:

FIG. 1 is a block diagram for showing one embodiment of the invention;

FIG. 2 is a flowchart for showing operations of a disk array apparatus shown in FIG. 1; and

FIG. 3 is a block diagram for showing a prior art disk array apparatus.

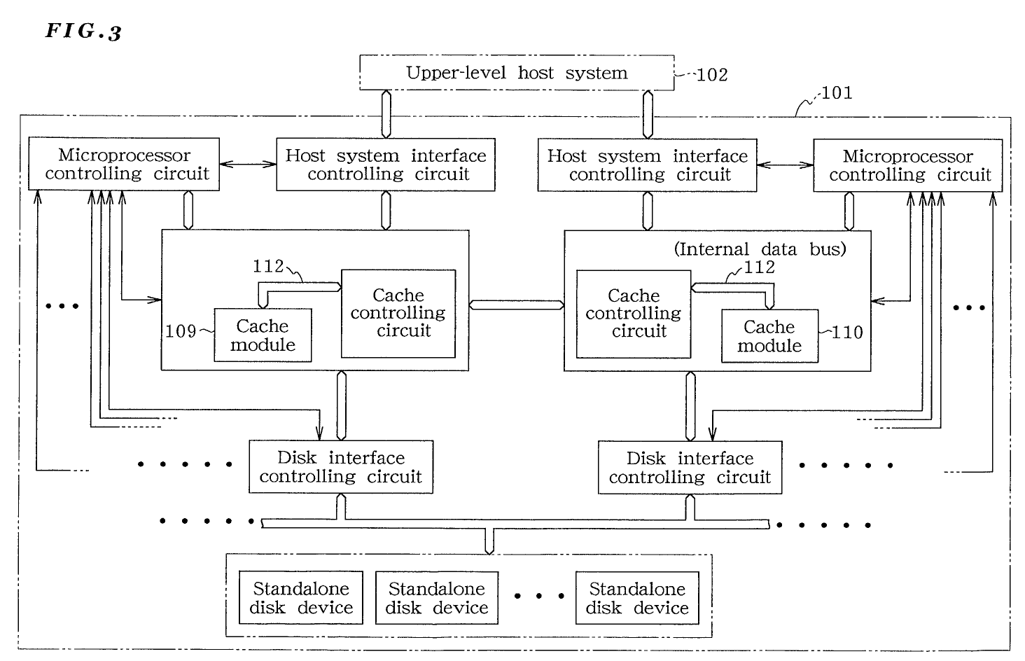

### DESCRIPTION OF THE PREFERRED EMBODIMENTS

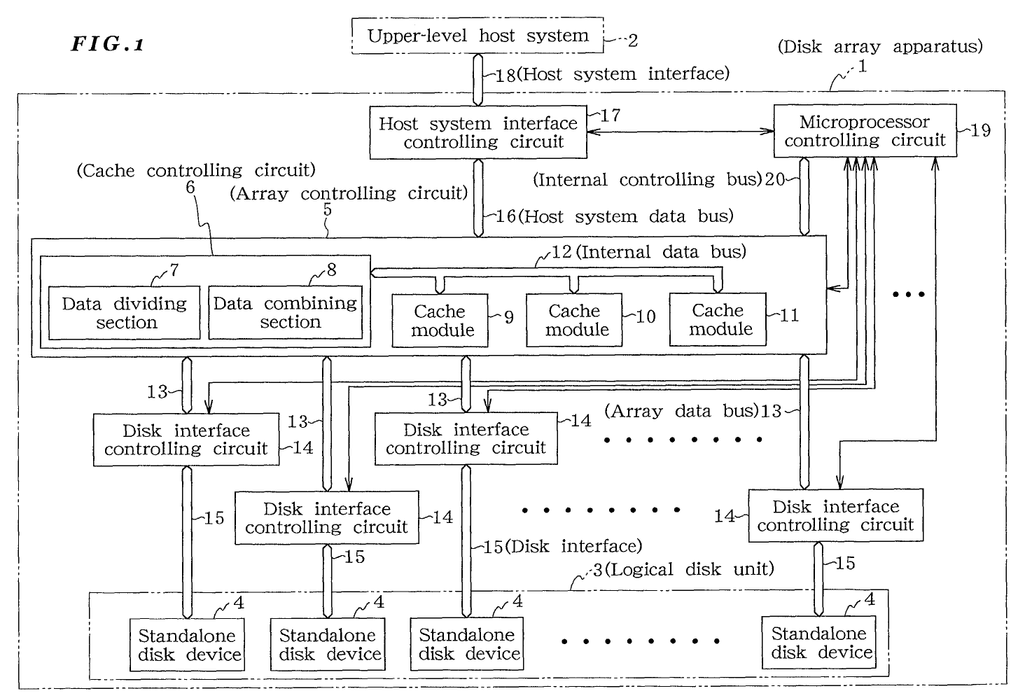

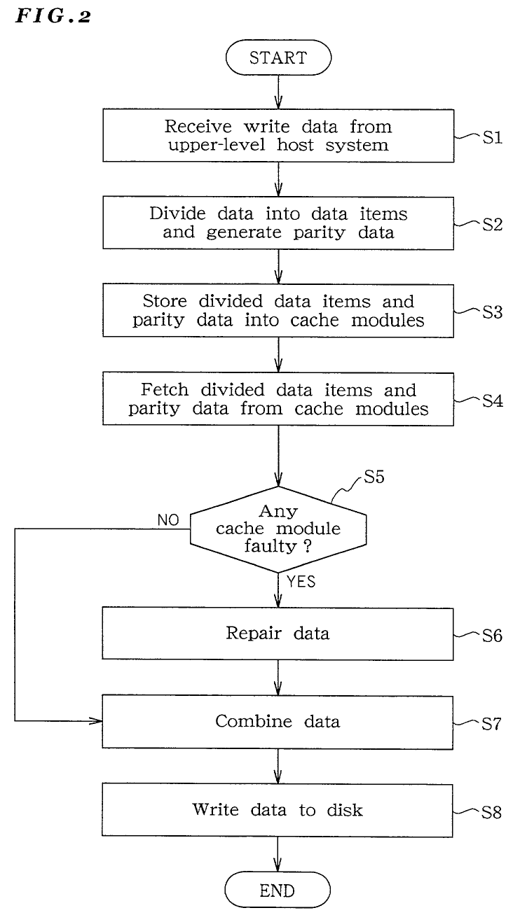

The following will describe one embodiment of the invention with reference to FIGS. 1 and 2.

FIG. 1 is a block diagram for showing a configuration of a disk array apparatus 1 of the invention. In FIG. 1, the disk array apparatus 1 comprises an array controlling unit 5 which has a function of receiving an instruction from an upper-level host system 2 to then write predetermined data to or read it out from a plurality of standalone disk units 4 as well as a data dividing function of dividing this predetermined data and a data combining function of combining the same.

The array controlling unit 5 includes a data dividing section 7 for dividing the above-mentioned predetermined data into a plurality of divided data items and also generate parity data based on the 20 predetermined data, a plurality of cache modules 9, 10, and 11 for temporarily storing thus divided data items and the parity data respectively, and a data combining section 8 for combining necessary data based on these divided data items and the parity data stored in these cache modules 9, 10, and 11, thus effecting the data dividing function and the data combining function for the above-mentioned predetermined data.

This will be detailed as follows.

As mentioned above, the disk array apparatus 1 is provided with the array controlling unit 5, to which is connected a logical disk unit 3 made up of a plurality of standalone disk devices 4.

Specifically, the array controlling unit 5 is connected to a plurality of disk interface controlling circuits 14 via a corresponding plurality of array data buses 13. Each of those disk interface circuits 14 is in turn connected via a corresponding disk interface 15 connected thereto to the above-mentioned standalone disk device 4.

In this configuration, when an instruction is received from the above-mentioned upper-level host system, data I/O operations are performed between the array control unit 5 and each of the disk devices 4.

Also, the array control unit 5 is connected to the above-mentioned upper-level host system 2. Specifically, the array control unit 5 is connected via a host system data bus 22b to the host system interface controlling circuit 17, which is in turn connected to the upper-level host system 2 via a host system interface 18.

Further, the above-mentioned host system interface controlling circuit 17 is connected to microprocessor controlling circuit 19 to thereby control the I/O operations of instruction and data between the upper-level host system 2 and the relevant components. This microprocessor controlling circuit 19 is connected to the array controlling unit 5 via an internal controlling bus 20.

As mentioned above, the array controlling unit 5 comprises the three cache modules 9, 10, and 11. Those three cache modules 9, 10, and 11 are all formed to have the same capacity. Those three cache modules 9, 10, and 11, however, need not have the same storage capacity and so may have different capacities. Also, those cache modules need not always be provided three.

The array controlling unit 5 is provided with also a cache controlling circuit 6 for controlling the data stored in those cache modules 9, 10, and 11. This cache controlling circuit 6 is in turn provided with the above-mentioned data dividing section 7 and the data combining section 8.

The data dividing section 7 first divides into a plurality of division data blocks D1 and D2 the predetermined data transferred from the host system 2 via the host system data bus 16 or from the standalone disk device 4 via the array data bus 13 and also generates parity data P. Then, the data dividing section 7 stores via the internal data bus 12 the division data block D1 in the cache module 9, the division data block D2 in the cache module 10, and the parity data P in the cache module 11.

The data combining section 8 combines the predetermined data to be transferred to the upper-level host system via the host system data bus 16 or to the standalone disk device 4 via the array data bus 13 based on a plurality of data blocks D1 and D1 and the parity data P stored via the internal data bus 12 in the cache modules 9, 10, and 11 respectively.

Those division data blocks D1 and D2 and the parity data P are set to have the same capacity. This can simplify the method for generating the divided data and the parity data, thus providing a higher processing rate at the array controlling unit 5.

Also, preferably the above-mentioned parity data is divided into data items as many as a number smaller than the number of the cache modules by one. That is, preferably the total number of the divided data items and the parity data items is equal to the number of the cache modules. Accordingly, supposing the number of the cache modules is N, up to a ratio of (N−1)/N of the capacity of the mounted caches can be assigned to the storage of transfer data, thus transferring the mass of data at a time. In this case, however, the number of the above-mentioned divided data items does not always depend on the number of the cache modules.

The following will describe operations and a method for controlling reading/writing of data according to this embodiment with respect to FIG. 2. That is, the operations of this embodiment effectuate the data read/write controlling method. FIG. 2 is a flowchart for showing the operations of this embodiment.

As shown in FIG. 2, the data read/write controlling method comprises a data receiving step of receiving from the upper-level host system the predetermined data to be written to a disk (step S1), data processing steps of executing predetermined processes on thus received data (steps S4, S5, S6, and S7), and a data write-in step of writing thus processed data to the disk (step S8).

To read out the data from the disk and transmit it to the upper-level host system, the method further comprises a data read-out step of reading the predetermined data to be sent to the upper-level host system, a data processing step of conducting predetermined processing on thus read out data, and a data transmitting step of transmitting thus processed data to the upper-level host system.

The above-mentioned data processing steps (steps S2, S3, S4, S5, S6, and S7) are divided into a data dividing step (step S2) of dividing data received at the data receiving step (step S1) into a plurality of data items and generating parity data, a data storing step (step S3) of storing thus divided data items and the parity data individually in the respective cache modules, a fetching step (step S4) for fetching those divided data items and the parity data from the cache modules, a detecting step (step S5) for detecting any damaged one of those divided data items, a data repairing step (step S6) for repairing the damaged divided data item, if detected at the step S5, based on the parity data, and a data combining step (step S7) for combining those divided data items.

Those steps are detailed as follows: first by the data receiving step, when the upper-level host system 2 issues an instruction, data to be written on the standalone disk device 4 (write data) is transmitted from the upper-level host system 2 via the host system interface 18, the host system interface controlling circuit 17, and the host system data bus 16 to the array controlling unit 5, which thus receives this write data (step S1)

Also, by the data read-out step, when the upper-level host system 2 issues an instruction, data to be read out from the standalone disk device 4 (read data) is sent from this standalone disk device 4 via the disk interface 15, the disk interface controlling circuit 14, and the array data bus 13 to the array controlling unit 5.

Next, by the data dividing step, the data (write data or read data) now present at the array controlling unit 5 is divided into a plurality of division data blocks D1 and D2 by the data dividing section 7 in the cache controlling circuit 6 and, at the same time, parity data P is generated (step S2).

Also, by the data storing step, the data dividing section 6 stores via the internal data bus 12 the division data block D1 in the cache module 9, the division data block D2 in the cache module 10, and the parity data P in the cache module 11 (step S3). The storage locations, however, are not limited to them.

Next, the plurality of data blocks D1 and D2 and the parity data P stored in the cache modules 9, 10, and 11 respectively are fetched (step S4) and checked for any damages (step S5), and if none of the divided data items is damaged, are combined as data by the data combining section 8 via the internal data bus 12 (step S7)

At the data write-in step, thus combined data, if to be written to any one of the standalone disk devices 4 of the logical disk unit 3, is transferred, according to an instruction from the upper-level host system 2, from the array controlling unit 5 via the array data bus 13, the disk interface controlling circuit 14, and the disk interface 15 to that one of the standalone disk devices 4, and written to that one standalone disk device 4 (step S8).

If to be read out from any one of the standalone disk devices 4, on the other hand, that combined data is transferred from the array controlling unit 5 via the host system data bus 15, the host system interface controlling circuit 17, and the host system interface 18 to the upper-level host system 2 at the data transmitting step.

The following will describe how to treat data if the cache module 9 fails (step S5).

As mentioned above, the cache modules 9, 10, and 11 store the division data block D1, the division data block D2, and the parity data P respectively. Accordingly, if the cache module 9 fails, the division data block D1 stored in this cache module 9 is discarded.

In this case, the division data block D2 and the parity data P stored in the other cache registers 10 and 11 are taken out of them by the above-mentioned data combining section 8 via the internal data bus 12.

Then, at the data repairing step, based on those division data block D2 and the parity data P, the division data block D1 is generated by this data combining section 8. That is, the division data block D1 once damaged when the cache module 9 failed is repaired (step S6).

Next, as mentioned above, those division data items are combined by the data combining section 8 (step S7), so that thus combined data is written to each of the standalone disks 4 (step S8) or transferred to the upper-level host system.

Also, the faulty cache module 9 is replaced with a new one by a person in charge of maintenance etc. After the cache module 9 is replaced, data is transferred again as mentioned above. In this case, however, even before the faulty cache module is replaced, the remaining normal cache modules can be used to transfer data.

Thus, if any one of the cache modules fails and, as a result, one divided data item corresponding thereto is discarded, the data can be combined based on the remaining divided data items and the parity data. Accordingly, the reliability can be maintained of the disk array apparatus during data transfer.

Also, as mentioned above, when the three cache modules 9, 10, and 11 are used, two-thirds of the capacity of the mounted caches can be used to store the transfer data. Therefore, supposing that the number of the cache modules is increased to N, up to a ratio of (N−1)/N of the capacity of the mounted caches can be assigned to the storage of transfer data to thereby utilize the cache memory effectively, thus transferring the mass of data.

Further, even before the faulty cache module is replaced by a person in charge of maintenance etc., the remaining normal cache modules can be utilized to transfer data. This avoids damaging of the I/O functions of the disk array apparatus, thus preventing its I/O performance from being deteriorated.

As mentioned above, the disk array apparatus according to the invention comprises the array controlling unit which receives an instruction from the upper-level host system to thereby write predetermined data to and read it out from a disk and also conduct operational processing on this predetermined data, which array controlling unit includes the data dividing function for dividing the predetermined data into at least two data items and also generating parity data for the predetermined data and the data combining function for repairing one of these divided data items, if it is damaged, using the parity data and also combining the divided data items, so that if one of the divided data items is damaged, this combining function can be utilized to repair that data item based on the parity data to thereby eliminate the need of mirroring transfer data and so suppress the data damages during data transfer between the upper-level host system and the disks, thus obtaining an excellent novel effect of enabling mass data transfer while maintaining a high reliability in transfer of the data.

Also, since the array controlling unit includes the data dividing section for dividing the predetermined data into at least two data items and also generating parity data based on this predetermined data, a plurality of cache modules for temporarily storing these divided data items and the parity data respectively, and the data combining section for repairing the divided data item stored in one of these cache modules, if it fails, using the other divided data items and the parity data and also combining the divided data items, so that if one of the cache modules fails and one of the divided data items stored therein is damaged, this damaged divided data item can be repaired by the data combining section based on the remaining divided data items and the parity data to thereby combine the data items in order to transfer the data using the remaining normal cache modules while maintaining a data transfer reliability and so prevent the I/O performance from being deteriorated, and also that supposing the number of the cache modules is N, up to a ratio of (N−1)/N of the capacity of the mounted caches can be assigned to the storage of the transfer data, thus obtaining an excellent novel effect of transferring the mass of data.

Also, if the cache modules are set to have an equal capacity or each divided data item and the part data are set to have an equal capacity, then each cache module or each divided data item and the parity data have an equal capacity, so that each divided data and the parity data need not be generated based on each capacity to thereby simplify the generation method, thus improving the processing rate and also providing an excellent effect of reducing the costs because a single type of cache modules can be used.

Also, if the total number of the divided data items and the parity data items is set equal to the number of the cache modules, the capacity of these cache modules can be utilized more effectively to thereby eliminate their idling operations, thus providing an excellent effect of improving the data transfer efficiency.

Further, if the number of the divided data items is set one smaller than the number of the cache modules, one of the cache modules can be assigned for storing the parity data to thereby assign the other cache modules for storing of the divided data items, thus giving an excellent effect of utilizing the capacity of the cache memory in data transfer further effectively for improved mass data transfer.

The invention may be embodied in other specific forms without departing from the spirit or essential characteristic thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No. 2000-177036 (Filed on Jun. 13, 2000) including specification, claims, drawings and summary are incorporated herein by reference in its entirety.

What is claimed is:

1. A method for controlling a data read/write operation comprising:
a data receiving step of receiving predetermined data to be written to a disk from an upper-level host system;
a data processing step of conducting predetermined processing on said received data; and
a data write-in step of writing said processed data to said disk,
wherein said data processing step comprises:
a data dividing step of dividing said data received at said data receiving step into a plurality of data items and also generating parity data;
a data storing step of individually storing said divided data items and said parity data items into cache modules respectively;
a data repairing step of fetching said divided data items and said parity data from said cache modules and repairing one of said divided data items, if said one is damaged, using said parity data; and
a data combining step of combining said divided data items.

2. A method for controlling a data read/write operation comprising:
a data read-out step of reading out predetermined data to be transmitted to an upper-level host system from a disk;
a data processing step of conducting predetermined processing on said read out data; and
a data transmitting step of transmitting said processed data to said upper-level host system,
wherein said data processing step comprises:
a data dividing step of dividing said data read out at said data read-out step into a plurality of data items and also generating parity data;
a data storing step of individually storing said divided data items and said parity data items into cache modules respectively;
a data repairing step of fetching said divided data items and said parity data from said cache modules and also repairing one of said divided data, if said one is damaged, using said parity data; and
a data combining step of combining said divided data.

3. A disk array apparatus comprising an array controlling unit for receiving an instruction from an upper-level host system to thereby write predetermined data to or read said predetermined data out from a disk and also conduct operational processing on said predetermined data, wherein said array controlling unit comprises:
a data dividing function for dividing said predetermined data into at least two data items and also generating parity data for said predetermined data; and
a data combining function for repairing one of said divided data items, if said one is damaged, using said parity data and also combining said divided data items.

4. A disk array apparatus comprising an array controlling unit for receiving an instruction from an upper-level host system to thereby write predetermined data to or reading said predetermined data from a disk and also conduct operational processing on said predetermined data, wherein said array controlling unit comprises:
a data dividing section for dividing said predetermined data into at least two data items and also generating parity data based on said predetermined data;
a plurality of cache modules for temporarily storing said divided data items and said parity data respectively; and
a data combining section for repairing said divided data item stored in one of said cache modules, if said one fails, using the remaining ones of said divided data items and said parity data and also combining said divided data.

5. The disk array apparatus according to claim 4, wherein said cache modules are set to have an equal capacity.

6. The disk array apparatus according to claim 4, wherein each of said divided data items and said parity data are set to have an equal capacity.

7. The disk array apparatus according to claim 4, 5, or 6, wherein a total number of said divided data items and said parity data items is set equal to a number of said cache modules.

8. The disk array apparatus according to claim 4, wherein a number of said divided data items is set one smaller than a number of a number of said cache modules.

9. A recording medium for recording a data read/write controlling program, said program comprising:
a data dividing process for receiving predetermined data to be written to a disk from an upper-level host system to then divide said predetermined data into a plurality of data items and also generate parity data;
a data storing process for individually storing said divided data items and said parity data into cache modules respectively;
a data repairing process for fetching said divided data items and said parity data from said cache modules to thereby repair one of said divided data item, if said one is damaged, using said parity data; and
a data combining process of combining said divided data items to then write this combined data to said disk.
